(19) United States
(12) Patent Application Publication
(10) Pub. No.: US 2024/0014000 A1
(43) Pub. Date: Jan. 11, 2024

(54) MINIATURE ELECTRON OPTICAL COLUMN WITH A LARGE FIELD OF VIEW

(71) Applicant: KLA Corporation, Milpitas, CA (US)

(72) Inventors: Alan D. Brodie, Palo Alto, CA (US); Lawrence P. Muray, Milpitas, CA (US); John Gerling, Livermore, CA (US)

(21) Appl. No.: 17/862,052

(22) Filed: Jul. 11, 2022

(51) Int. Cl. H01J 37/141; H01J 37/153

(52) U.S. Cl. CPC H01J 37/141; H01J 37/153; H01J 37/147

(57) ABSTRACT

A miniature electron optical column apparatus is disclosed. The apparatus may include a set of electron-optical elements configured to direct a primary electron beam to a sample. The set of electron-optical elements may include an objective lens. The apparatus may also include a deflection sub-system. The deflection sub-system may include one or more pre-lens deflectors positioned between an electron beam source and the objective lens. The deflection sub-system may also include a post-lens deflector positioned between the objective lens and the sample. The deflection sub-system may also include a post-lens miniature optical element positioned between the objective lens and the sample.

### TECHNICAL FIELD

The present invention generally relates to a miniature electron optical column, and more particularly, to a deflection system for a miniature electron optical column to produce a large field of view.

### BACKGROUND

Characterization systems identify and classify defects on semiconductor wafers to generate a defect population on the sample. Characterization systems may include optical characterization systems, and charged particle characterization systems, such as electron-beam systems. In the context of electron-beam characterization systems, electron beams are directed to the sample, and detectors are configured to collect secondary and/or backscattered electrons emanated from the sample in order to characterize the sample.

In electron-beam characterization systems, the resolution at the corners of the scan field is limited by the deflection aberrations of the system. To overcome these aberrations a correction element is needed. In current electron-beam characterization systems, the correction element is placed either before the objective lens or in the bore of the objective lens. However, as the size of the electron-optical column of the electron-beam characterization system decreases, the bore diameter of the objective lens decreases. With the decrease in bore diameter of the objective lens, it becomes more difficult to insert the in-lens correction elements within the bore of the objective lens.

Therefore, it would be desirable to provide a system and method that cures the shortfalls of the previous approaches identified above.

### SUMMARY

A large field of view (FOV) miniature electron optical column apparatus is disclosed, in accordance with one or more embodiments of the present disclosure. In one embodiment, the apparatus includes a set of electron-optical elements configured to direct a primary electron beam of an electron beam source to a sample, the set of electron-optical elements including an objective lens. In another embodiment, the apparatus includes a deflection sub-system. In another embodiment, the deflection sub-system includes one or more pre-lens deflectors positioned between the electron beam source and the objective lens. In another embodiment, the deflection sub-system includes a post-lens deflector positioned between the objective lens and the sample. In another embodiment, the deflection sub-system includes a post-lens miniature optical element positioned between the objective lens and the sample.

In one embodiment, the miniature column optical column apparatus may be integrated within a characterization system.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures in which:

FIG. 1 illustrates a simplified schematic of a miniature electron optical column integrating the deflection system, in accordance with one or more embodiments of the present disclosure.

FIG. 2A illustrates a simplified schematic of a deflection system not capable of applying post-lens correction.

FIG. 2B illustrates a simplified schematic of the deflection system capable of applying one technique of post-lens correction, in accordance with one or more embodiments of the present disclosure.

FIG. 3 illustrates a simplified schematic of a possible scanning field, where the post-lens deflectors are split into a main field and a sub-field, in accordance with one or more embodiments of the present disclosure.

FIG. 4 illustrates a flowchart depicting a method or process for applying one or more corrections using the deflection system, in accordance with one or more embodiments of the present disclosure.

FIG. 5 illustrates a simplified schematic block diagram of a multi-column characterization system integrating the deflection system, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to a deflection system for a miniature electron beam column. More particularly, embodiments of the present disclosure are directed to a deflection system configured to maximize the scan size of the miniature electron optical column by placing one or more components of the deflection system between an objective lens and a sample and one or more components of the deflection system between an electron beam source and the objective lens.

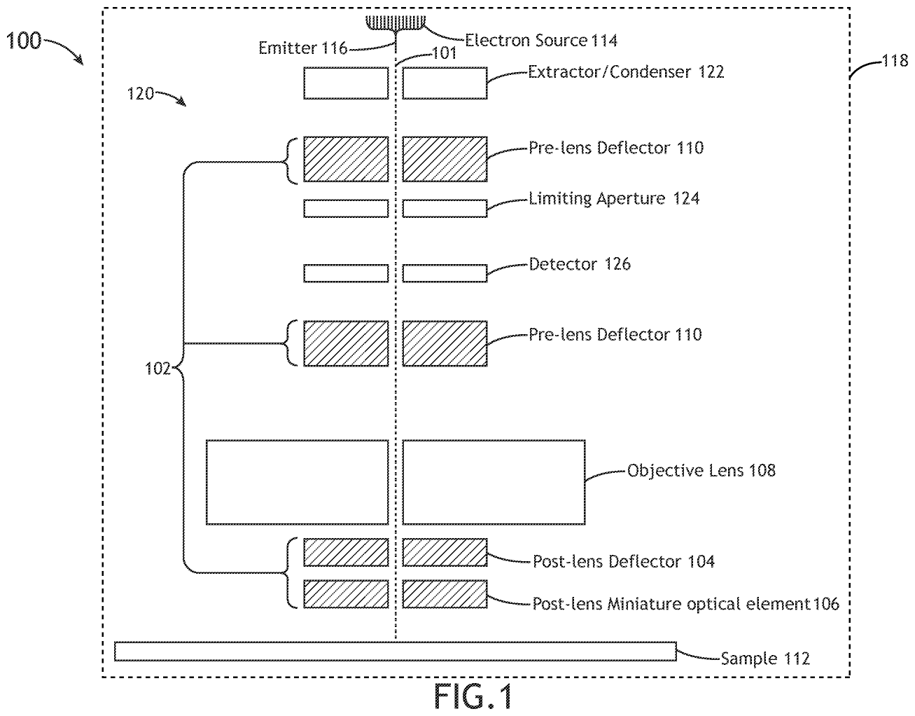

FIG. 1 illustrates a simplified schematic of a miniature electron optical column 100 integrating a deflection system 102, in accordance with one or more embodiments of the present disclosure.

In embodiments, the deflection system 102 includes a post-lens deflector 104 and a post-lens miniature optical element 106. The post-lens deflector 104 and the post-lens miniature optical element 106 may be positioned a select position between the objective lens 108 and a sample 112. By placing one or more components of the deflection system 102 a select position below the objective lens 108, the scan size of deflection system 102 may be maximized such that the miniature electron optical column 100 may have a large field of view.

The post-lens miniature optical element 106 may include any miniature optical element known in the art. For example, the post-lens miniature optical element 106 may include one or more extraction control electrode. By way of another example, the post-lens miniature optical element 106 may include one or more shield electrodes. By way of another example, the post-lens miniature optical element 106 may include a post-lens detector. By way of another example, the post-lens miniature optical element 106 may include one or more additional post-lens deflectors. By way of another example, the post-lens miniature optical element 106 may include one or more electrostatic lenses. By way of another example, the post-lens miniature optical element 106 may include one or more miniature magnetic deflectors.

The post-lens deflector 104 and the post-lens miniature optical element 106 may be formed using one or more silicon micromachining techniques and one or more microelectromechanical (MEMS) materials (e.g., silicon and borosilicate glass).

In addition, the deflection system 102 may include one or more pre-lens deflectors 110. In embodiments, the one or more pre-lens deflectors 110 are positioned a select position above a bore of the objective lens 108. For example, as shown in FIG. 1, the one or more pre-lens deflectors 110 may be positioned between the objective lens 108 and an electron beam source 114.

In embodiments, the one or more deflectors 104, 110 may be configured for alignment and deflection of the primary beam 101. For example, the one or more deflectors 104, 110 may include one or more electrostatic octupole deflectors. By way of another example, the one or more deflectors may include one or more electrostatic quadrupole deflectors. By way of another example, the one or more deflectors may include one or more electrostatic dodecapole deflectors.

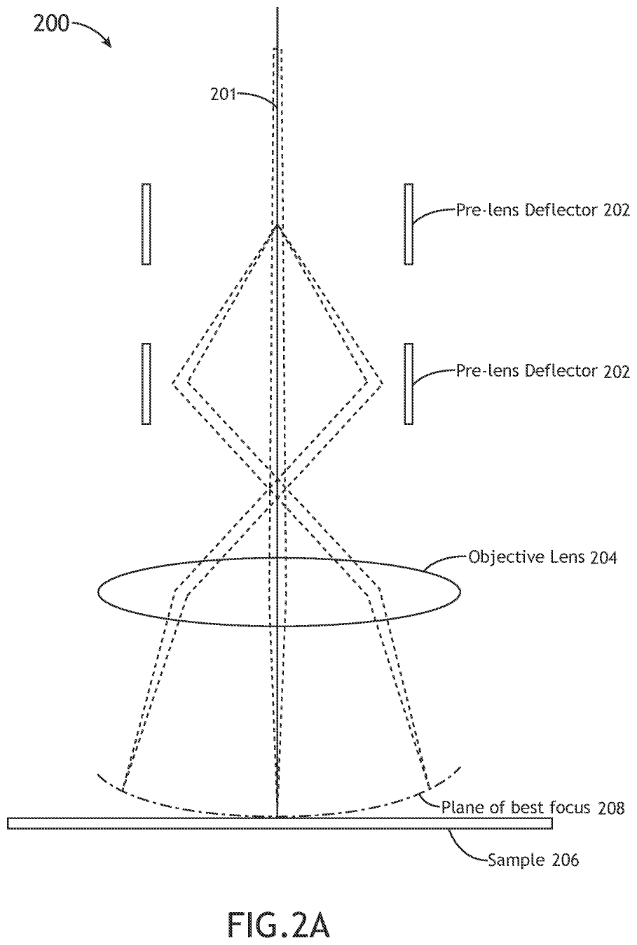

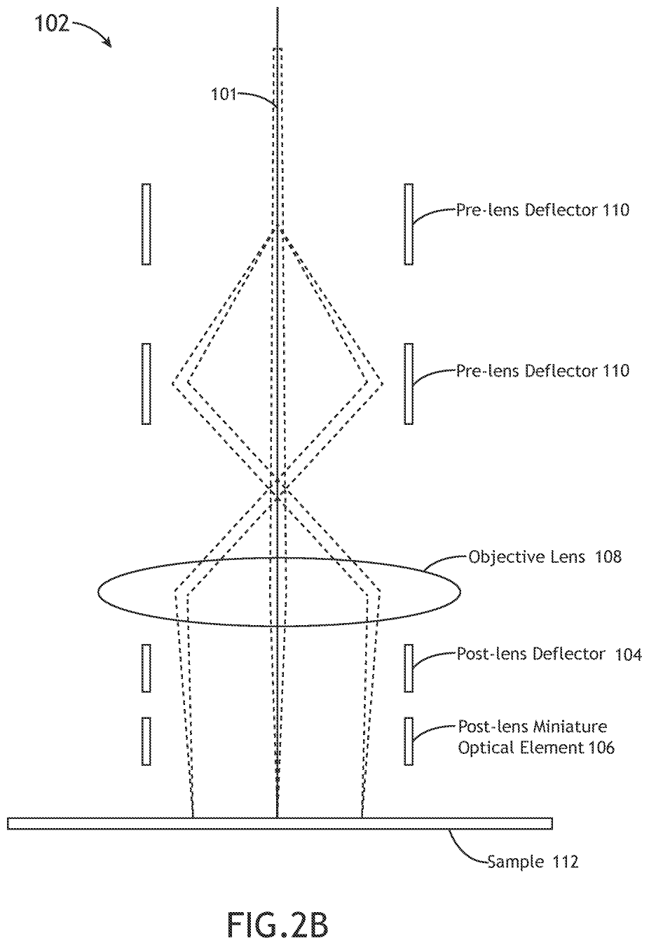

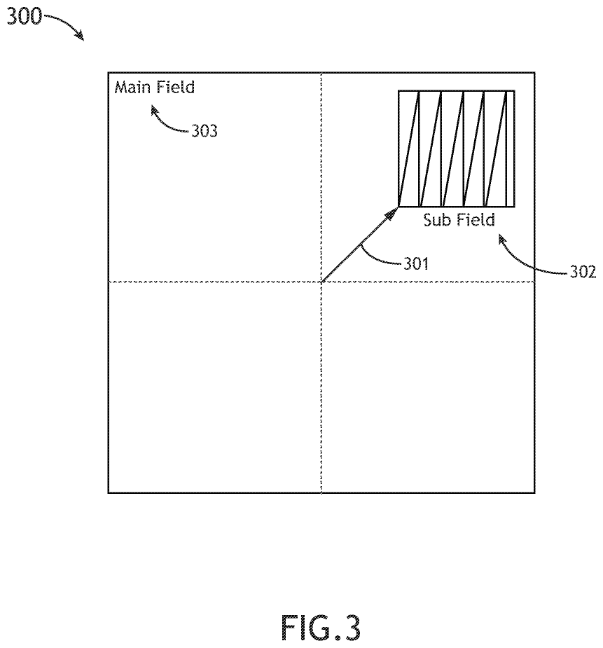

In embodiments, the one or more pre-lens deflectors 110 are configured to perform coordinated deflection, either in-phase or out-of-phase in order to maximize the scan field at the sample 112. For example, the one or more pre-lens deflectors 110 may be operated in pairs or groups in order to split the full scan field (e.g., main field) into several sub-fields. For instance, the deflection system 102 may include one or more upper pre-lens deflectors 110 and one or more lower pre-lens deflectors 110, where the one or more upper pre-lens deflectors 110 and the one or more lower pre-lens deflectors 110 are configured to be operated in pairs or groups to split the full scan field into several sub-fields. In this regard, correction signals may be applied on top of the deflection signals from the one or more pre-lens deflectors 110 (e.g., one or more upper pre-lens deflections 110 or one or more lower pre-lens deflectors 110) to counteract aberrations of the primary beam 101, including astigmatism and/or misalignment. Such configurations are discussed in further detail in FIGS. 2A-3.

The one or more pre-lens deflectors 110 may be formed using one or more silicon micromachining techniques and one or more microelectromechanical (MEMS) materials (e.g., silicon and borosilicate glass).

The deflection system 102 may be integrated with any type of objective lens 108. For example, the objective lens 108 may include a magnetic objective lens. For instance, the objective lens 108 may include a permanent magnetic objective lens. By way of another example, the objective lens 108 may include an electrostatic objective lens. Permanent magnetic objective lenses are generally discussed in U.S. patent application Ser. No. 17/658,637, filed on Apr. 8, 2022,which is incorporated by reference in the entirety.

The objective lens 108 may have a small-bore diameter. For example, the objective lens 108 may have a bore diameter less than 4 mm. By way of another example, the objective lens 108 may have a bore diameter less than 2 mm. By way of another example, the objective lens 108 may have a bore diameter less than 1 mm. It is noted that it may be difficult to insert one or more correction elements within the bore of the objective lens due to the small size of the bore, therefore, one or more components of the deflection system 102 may be placed below the objective lens 108, which maximizes the scan size of the column 100 to produce a large field of view.

In embodiments, the deflection system 102 is configured to augment deflection of one or more components of the deflection system 102. For example, the post-lens deflector 104 may be configured to augment deflection of the one or more pre-lens deflectors 110.

In embodiments, the deflection system 102 is configured to apply one or more corrections to the primary electron beam 101. For example, the deflection system 102 may be configured to apply one or more corrections to correct for astigmatism. In one instance, the one or more pre-lens deflectors 110 may be configured to apply post-lens correction to correct for astigmatism. In another instance, the post-lens deflector 104 may be configured to apply post-lens correction to correct for astigmatism. In another instance, the post-lens miniature optical element 106 may be configured to apply post-lens correction to correct for astigmatism.

FIGS. 2A-2B illustrate deflection systems 102, 200 with and without post-lens correction, respectively. As shown in FIG. 2A, a deflection system 200 may include one or more pre-lens deflectors 202 and an objective lens 204 positioned above a sample 206. In this case, the deflection system 200 is not capable of applying post-lens correction to correct for field curvature, causing the plane of best focus 208 for the primary beam 201 to be a curved field. In contrast, as shown in FIG. 2B, in the case where the deflection system 102 is capable of applying post-lens correction to correct for field curvature, the plane of best focus for the primary beam 101 is flat, rather than curved, thereby ensuring good focus across the portion of the sample 112 inspected by the beam 101. The deflection system 102 may be configured to apply one or more corrections to correct for field curvature, as shown in FIG. 2B. In one instance, the post-lens deflector 104 may be configured to apply post-lens correction to correct for field curvature. In another instance, the post-lens miniature optical element 106 may be configured to apply post-lens correction to correct for field curvature.

By way of another example, the deflection system 102 may be configured to apply one or more corrections to correct for offsets. In one instance, the post-lens deflector 104 may be configured to apply offset correction. In another instance, the one or more pre-lens deflectors 110 may be configured to apply one or more corrections to correct for offsets. In another instance, the post-lens miniature optical element 106 may be configured to apply offset correction.

In embodiments, the deflection system 102 is configured to apply dynamic focus correction to the primary electron beam 101. For example, the post-lens miniature optical element 106 may be configured to apply dynamic focus correction to the primary electron beam 101. By way of another example, the post-lens deflector 104 may be configured to apply dynamic focus correction to the primary electron beam 101.

In embodiments, the deflection system 102 is configured for scanning. For example, the one or more pre-lens deflectors 110 may be configured for scanning. By way of another example, the post-lens deflector 104 may be configured for scanning. By way of another example, the post-lens miniature optical element 106 may be configured for scanning.

It is noted that one or more components of the deflection system 102 may be configured to perform scanning, while an additional component of the deflection system 102 may be configured to perform an additional function (e.g., scanning, offset correction, or the like). For example, as shown in FIG. 3, the one or more pre-lens deflectors 110 may be configured to offset the position of the primary electron beam 101 while the post-lens miniature optical element 106 may be configured for scanning.

As shown in FIG. 3, the position of the beam may be modified by the one or more pre-lens deflectors 110 to place the small scan generated by the post-lens miniature optical element 106 within any portion of the main field 303 (e.g., the range of the one or more pre-lens deflectors 110). For example, the small scan of the post-lens miniature optical element 106 may be positioned within a subfield 302 of the main field 303. In this example, the subfield origin position 301 of the beam may be modified by the one or more pre-lens deflectors 110 to place the small scan within the subfield 302.

In embodiments, the scanning may be static or dynamic. For example, when the scanning is static, a sample stage may be static (not moving) and the beam may scan the subfield 302 at some offset 301. By way of another example, when the scanning is dynamic, the sample stage may be dynamic (moving) and the scan field may need to track the movement as the defect moves across the main field 303. In this example, the vector position 301 may be configured to track the movement of the sample stage.

It is noted that as the beam scans across the main field 303, the one or more corrections from the post-lens deflector 104 are added.

In embodiments, the deflection system 102 is configured to vary an extraction field from the sample 112. For example, the post-lens miniature optical element 106 may be configured to vary an extraction field from the sample. For instance, the post-lens miniature optical element 106 may include an extraction control electrode 106 configured to vary the extraction field from the sample.

In embodiments, the deflection system 102 may be configured to vary a termination field. For example, the post-lens miniature optical element 106 may be configured to vary a termination field.

In embodiments, the deflection system 102 may be configured to vary a focusing element. For example, the post-lens miniature optical element 106 may be configured to vary a focusing element.

It is noted that the deflection system 102 may be configured to perform a plurality of functions simultaneously. For example, the deflection system 102 may be configured to perform scanning, astigmatism correction, offset correction, or field curvature correction simultaneously.

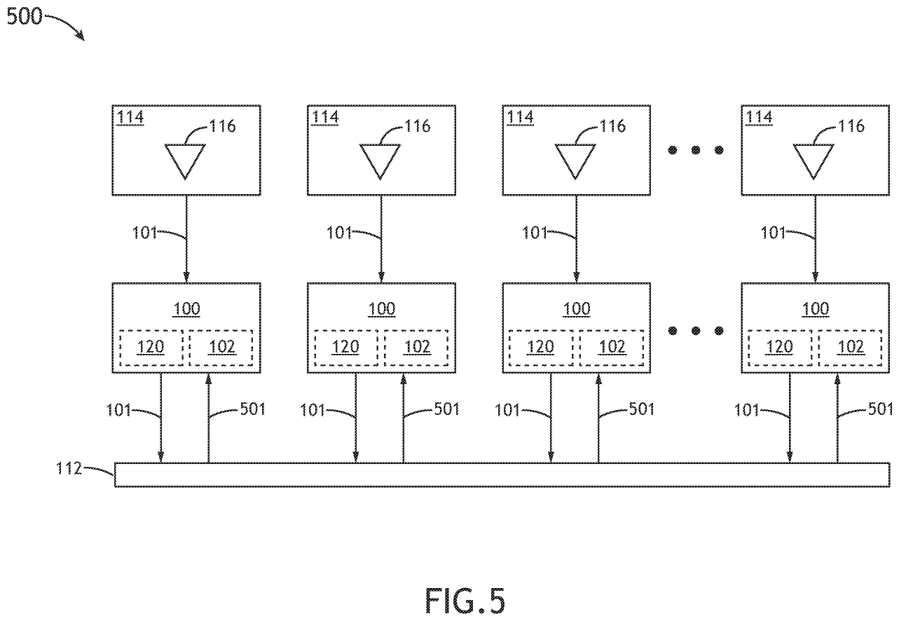

Referring again to FIG. 1, the deflection system 102 may be integrated within a miniature electron optical column 100. Such a miniature electron optical column 100 may be utilized within a multi-column characterization system (e.g., system 500 shown in FIG. 5). It is noted that the deflection system 102 may be configured to maximize the scan size of the miniature electron optical column 100 to produce a large field of view. It is noted that the description of the various embodiments, components, and operations described previously herein with respect to the deflection system 102 should be interpreted to extend to the miniature optical electron column 100, and vice versa.

In embodiments, the miniature electron optical column 100 includes an electron source 114. The electron source 114 may include an emitter 116. The miniature electron optical column 100 may include any type of electron source including, but not limited to, a field emission gun (FEG). The FEG may include, but is not limited to, a Schottky-type emitter, carbon nanotube emitter, nanostructured carbon emitter, a Muller-type emitter, a Spindt-type emitter, or the like.

In embodiments, the miniature electron optical column 100 may include a set of electron-optical elements 120. The various electron-optical elements of the miniature electron optical column 100 may be disposed within a vacuum chamber 118.

The set of electron-optical elements 120 may include, but are not required to include, an extractor/condenser lens 122, a beam limiting aperture 124, and a detector 126. Although FIG. 1 depicts a specific electron-optical element configuration, it is noted that such depiction is provided merely for illustrative purposes and shall not be construed as a limitation on the scope of the present disclosure.

In embodiments, the detector 126 may be configured to collect secondary and/or backscattered electrons 501 emanated from the surface of the sample 112 in response to the primary electron beam. The detector 126 may include any type of detector known in the art including, but not limited to, a photodiode, an avalanche photodiode, a photomultiplier tube, a scintillator, a micro-channel plate, or the like.

In embodiments, the miniature electron optical column 100 is communicatively coupled to a controller. The controller may include, but is not limited to, one or more processors, memory, detector amplifier and digitizer, one or more component power supplies, and the like. The controller may transmit and/or receive data from any component of the miniature electron optical column 100 and store the data in memory. The one or more processors may be configured to execute program instructions maintained on memory medium (memory). In this regard, the one or more processors of controller may execute any of the various process steps described throughout the present disclosure. For example, the one or more processors of the controller may be configured to determine an astigmatism correction. For instance, the one or more processors may be configured to determine an astigmatism correction based on at least one of an analytical function or a look-up table stored in memory. By way of another example, the one or more processors of the controller may be configured to determine a focus correction. For instance, the one or more processors may be configured to determine a focus correction based on at least one of an analytical function or a look-up table stored in memory.

In embodiments, the controller is connected to one or more elements of the miniature electron optical column 100. For example, the controller may be connected to one or more elements of the deflection system 102, such that the controller may be configured to adjust one or more characteristics of the primary beam via the one or more elements of deflection system. For instance, the controller may be configured to adjust one or more characteristics of the primary beam based on at least one of the determined focus correction or the determined astigmatism correction.

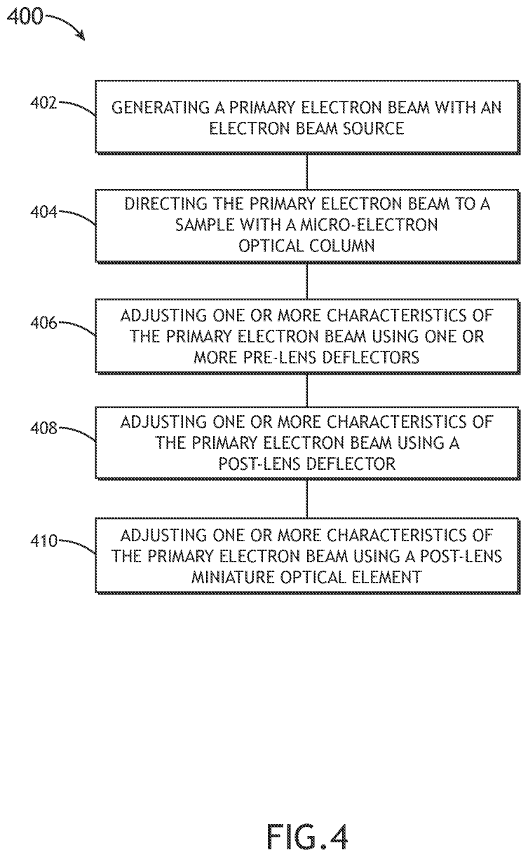

FIG. 4 illustrates a flow diagram depicting a method or process 400 for applying one or more corrections using the deflection system 102, in accordance with one or more embodiments of the present disclosure. It is noted that the steps of method 400 may be implemented all or in part by the deflection system 102. It is further recognized, however, that the method 400 is not limited to the deflection system 102 in that additional or alternative system-level embodiments may carry out all or part of the steps of method 400.

In step 402, a primary electron beam may be generated using the electron beam source. For example, the electron beam source 114 may be configured to generate an electron beam 101 and direct the primary electron beam 101 to the sample 112.

In step 404, the primary electron beam may be directed to a sample 112 with a miniature electron optical column. For example, the miniature electron optical column 100 may include a set of electron-optical elements 120 configured to receive the primary electron beam 101 and direct the primary electron beam 101 to the sample 112. The set of electron-optical elements 120 may include any electron-optical elements known in the art including, but not limited to, beam-limiting apertures, deflectors, electron-optical lenses, condenser lenses (e.g., magnetic condenser lenses), an objective lens (e.g., magnetic objective lens or electrostatic objective lens), and the like.

In step 406, one or more characteristics of the primary electron beam may be adjusted using one or more pre-lens deflectors. For example, the one or more pre-lens deflectors 110 may be configured to apply one or more dynamic focus corrections to the primary electron beam 101.

In step 408, one or more characteristics of the primary electron beam may be adjusted using a post-lens deflector. For example, the post-lens deflector 104 may be configured to augment deflection of the one or more pre-lens deflectors 110. By way of another example, the post-lens deflector 104 may be configured to apply one or more corrections to the primary electron beam 101. In one instance, the post-lens deflector 104 may be configured to apply one or more corrections to the primary electron beam 101 to correct for astigmatism. In another instance, the post-lens deflector 104 may be configured to apply one or more corrections to the primary electron beam 101 to correct for field curvature. In another instance, the post-lens deflector 104 may be configured to apply one or more corrections to the primary electron beam 101 to correct for offsets.

In step 410, one or more characteristics of the primary electron beam may be adjusted using a post-lens miniature optical element. For example, the post-lens miniature optical element 106 may be configured to vary an extraction field from the sample 112.

FIG. 5 illustrates a simplified schematic block diagram of a multi-column characterization system 500 integrating the deflection system 102, in accordance with one or more embodiments of the present disclosure. It is noted that the description of the various embodiments, components, and operations described previously herein with respect to the deflection system 102 and the electron column 100 should be interpreted to extend to the multi-column characterization system 500, and vice versa.

As shown in FIG. 5, the deflection system 102 may be integrated within a characterization system 500. It is noted that the characterization system 500 may include, but is not limited to, an inspection system or a metrology system. For the purposes of the present disclosure, it is noted that the characterization system 500 may be referred to as a characterization tool. Likewise, a metrology system may be referred to as a metrology tool, and an inspection system may be referred to as an inspection tool.

In embodiments, as shown in FIG. 5, the characterization system 500 is a multi-column characterization system 500. In this embodiment, the multi-column characterization system 500 may include a plurality of miniature electron optical columns 100 (e.g., miniature columns), where each miniature electron optical column 100 includes the deflection system 102. For example, the multi-column characterization system 500 may include a first miniature electron optical column, a second miniature electron optical column, a third miniature electron optical column, and up to an N number of miniature electron optical columns. Multi-column electron-beam characterization systems are generally discussed in U.S. Pat. No. 10,545,099, entitled Ultra-High Sensitivity Hybrid Inspection with Full Wafer Coverage Capability, issued on Jan. 28, 2020, which is incorporated by reference in the entirety. Multi-column electron-beam characterization systems are generally discussed in U.S. patent application Ser. No. 17/658,637, filed on Apr. 8, 2022, which is incorporated by reference in the entirety.

Although FIG. 5 depicts a specific electron-optical column configuration, it is noted that such depiction is provided merely for illustrative purposes and shall not be construed as a limitation on the scope of the present disclosure. The system 500 may include any number of electron columns 100 integrating the deflection system 102. For example, the system 500 may include a single column 100 integrating a single deflection system 102.

The sample 112 may include any sample known in the art including, but not limited to, a photomask, a reticle, a wafer, or the like. As used through the present disclosure, the term “wafer” refers to a substrate formed of a semiconductor and/or a non-semiconductor material. For instance, in the case of a semiconductor material, the wafer may be formed from, but is not limited to, monocrystalline silicon, gallium arsenide, and/or indium phosphide. As such, the term “wafer” and the term “sample” may be used interchangeably in the present disclosure. Therefore, the above description should not be interpreted as a limitation on the scope of the present disclosure but merely an illustration.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mate-able and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “ a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “ a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A large field of view miniature electron optical column apparatus, comprising:
a set of electron-optical elements configured to direct a primary electron beam of an electron beam source to a sample, the set of electron-optical elements comprising:
an objective lens; and
a deflection sub-system comprising:
one or more pre-lens deflectors positioned between the electron beam source and the objective lens;
a post-lens deflector positioned between the objective lens and the sample; and
a post-lens miniature optical element positioned between the objective lens and the sample.

2. The miniature electron optical column apparatus of claim 1, wherein the post-lens deflector is configured to augment deflection of the one or more pre-lens deflectors positioned between the electron beam source and the objective lens.

3. The miniature electron optical column apparatus of claim 1, wherein the post-lens deflector is configured to apply one or more corrections to the primary electron beam.

4. The miniature electron optical column apparatus of claim 3, wherein the one or more corrections are configured to correct for at least one of:
astigmatism, field curvature, or offsets.

5. The miniature electron optical column apparatus of claim 1, wherein the post-lens deflector is configured to apply one or more dynamic focus corrections to the primary electron beam.

6. The miniature electron optical column apparatus of claim 1, wherein the post-lens deflector is configured for scanning.

7. The miniature electron optical column apparatus of claim 1, wherein the post-lens deflector includes a silicon post-lens deflector.

8. The miniature electron optical column apparatus of claim 1, wherein the post-lens miniature optical element is configured to apply one or more corrections to the primary electron beam.

9. The miniature electron optical column apparatus of claim 8, wherein the one or more corrections are configured to correct for at least one of:
astigmatism, field curvature, or offsets.

10. The miniature electron optical column apparatus of claim 1, wherein the post-lens miniature optical element is configured to apply one or more dynamic focus corrections to the primary electron beam.

11. The miniature electron optical column apparatus of claim 1, wherein the post-lens miniature optical element is configured for scanning.

12. The miniature electron optical column apparatus of claim 1, wherein the post-lens miniature optical element is configured to vary an extraction field from the sample.

13. The miniature electron optical column apparatus of claim 1, wherein the post-lens miniature optical element is configured to vary a termination field.

14. The miniature electron optical column apparatus of claim 1, wherein the post-lens miniature optical element is configured to vary a focusing element.

15. iature electron optical column apparatus of claim 1, wherein the post-lens miniature optical element is formed of silicon.

16. The miniature electron optical column apparatus of claim 1, wherein the post-lens miniature optical element includes a post-lens detector.

17. The miniature electron optical column apparatus of claim 1, wherein the post-lens miniature optical element includes an extraction control electrode.

18. The miniature electron optical column apparatus of claim 1, wherein the post-lens miniature optical element includes a shield electrode.

19. The miniature electron optical column apparatus of claim 1, wherein the post-lens miniature optical element includes an additional post-lens deflector.

1. iature electron optical column apparatus of claim 1, wherein the post-lens miniature optical element includes an electrostatic lens.

21. The miniature electron optical column apparatus of claim 1, wherein the one or more pre-lens deflectors are configured to apply one or more corrections to the primary electron beam.

22. The miniature electron optical column apparatus of claim 21, wherein the one or more corrections are configured to correct for at least one of:
astigmatism or offsets.

23. The miniature electron optical column apparatus of claim 1, wherein the one or more pre-lens deflectors are configured for scanning.

24. The miniature electron optical column apparatus of claim 1, wherein the one or more pre-lens deflectors include one or more silicon pre-lens deflectors.

25. The miniature electron optical column apparatus of claim 1, wherein the objective lens has a bore diameter less than 4 mm.

26. The miniature electron optical column apparatus of claim 25, wherein the objective lens has a bore diameter less than 2 mm.

27. The miniature electron optical column apparatus of claim 26, wherein the objective lens has a bore diameter less than 1 mm.

28. A multi-column characterization system, comprising:
one or more electron beam sources configured to generate an array of primary electron beams;
a plurality of miniature electron optical columns, each miniature electron optical column of the plurality of miniature electron optical columns comprising:
a set of electron-optical elements configured to direct a primary electron beam to a sample, the set of electron-optical elements comprising:
an objective lens; and
a deflection sub-system comprising:
one or more pre-lens deflectors positioned between an electron beam source and the objective lens;
a post-lens deflector positioned between the objective lens and the sample; and
a post-lens miniature optical element positioned between the objective lens and the sample.

29. The multi-column characterization system of claim 28, wherein the post-lens deflector is configured to augment deflection of the one or more pre-lens deflectors positioned between the electron beam source and the objective lens.

30. The multi-column characterization system of claim 28, wherein the post-lens deflector is configured to apply one or more corrections to the primary electron beam.

31. The multi-column characterization system of claim 30, wherein the one or more corrections are configured to correct for at least one of:
astigmatism, field curvature, or offsets.

32. The multi-column characterization system of claim 28, wherein the post-lens deflector is configured to apply one or more dynamic focus corrections to the primary electron beam.

33. The multi-column characterization system of claim 28, wherein the post-lens deflector is configured for scanning.

34. The multi-column characterization system of claim 28, wherein the post-lens deflector includes a silicon post-lens deflector.

28. i-column characterization system of claim 28, wherein the post-lens miniature optical element is configured to apply one or more corrections to the primary electron beam.

36. The multi-column characterization system of claim 35, wherein the one or more corrections are configured to correct for at least one of:
astigmatism, field curvature, or offsets.

37. The multi-column characterization system of claim 28, wherein the post-lens miniature optical element is configured to apply one or more dynamic focus corrections to the primary electron beam.

38. The multi-column characterization system of claim 28, wherein the post-lens miniature optical element is configured for scanning.

39. The multi-column characterization system of claim 28, wherein the post-lens miniature optical element is configured to vary an extraction field from the sample.

28. i-column characterization system of claim 28, wherein the post-lens miniature optical element is configured to vary a termination field.

41. The multi-column characterization system of claim 28, wherein the post-lens miniature optical element is configured to vary a focusing element.

42. The multi-column characterization system of claim 28, wherein the post-lens miniature optical element is formed of silicon.

43. The multi-column characterization system of claim 28, wherein the post-lens miniature optical element includes a post-lens detector.

44. The multi-column characterization system of claim 28, wherein the post-lens miniature optical element includes an extraction control electrode.

28. i-column characterization system of claim 28, wherein the post-lens miniature optical element includes a shield electrode.

46. The multi-column characterization system of claim 28, wherein the post-lens miniature optical element includes an additional post-lens deflector.

47. The multi-column characterization system of claim 28, wherein the post-lens miniature optical element includes an electrostatic lens.

48. The multi-column characterization system of claim 28, wherein the one or more pre-lens deflectors are configured to apply one or more corrections to the primary electron beam.

49. The multi-column characterization system of claim 48, wherein the one or more corrections are configured to correct for at least one of:
astigmatism or offsets.

28. i-column characterization system of claim 28, wherein the one or more pre-lens deflectors are configured for scanning.

51. The multi-column characterization system of claim 28, wherein the one or more pre-lens deflectors include one or more silicon pre-lens deflectors.

52. The multi-column characterization system of claim 28, wherein the objective lens has a bore diameter less than 4 mm.

53. The multi-column characterization system of claim 52, wherein the objective lens has a bore diameter less than 2 mm.

54. The multi-column characterization system of claim 53, wherein the objective lens has a bore diameter less than 1 mm.

55. A method, comprising:
generating a primary electron beam with an electron beam source;
directing the primary electron beam to a sample with a miniature electron optical column;
adjusting one or more characteristics of the primary electron beam using one or more pre-lens deflectors positioned between the electron beam source and an objective lens of the miniature electron optical column;
adjusting one or more characteristics of the primary electron beam using a post-lens deflector positioned below the objective lens of the miniature electron optical column;
and adjusting one or more characteristics of the primary electron beam using a post-lens miniature optical element positioned below the objective lens of the miniature electron optical column.

56. The method of claim 55, wherein the adjusting one or more characteristics of the primary electron beam using a post-lens deflector positioned below an objective lens of the miniature electron optical column comprises:
augmenting deflection of the one or more pre-lens deflectors positioned between the electron beam source and the objective lens.

57. The method of claim 55, wherein the adjusting one or more characteristics of the primary electron beam using a post-lens deflector positioned below an objective lens of the miniature electron optical column comprises:
applying one or more corrections to primary electron beam.

58. The method of claim 57, wherein the one or more corrections are configured to correct for at least one of:
astigmatism, field curvature, or offsets.

59. The method of claim 55, wherein the adjusting one or more characteristics of the primary electron beam using a post-lens deflector positioned below an objective lens of the miniature electron optical column comprises:
applying one or more dynamic focus corrections to the primary electron beam.

55. od of claim 55, wherein the adjusting one or more characteristics of the primary electron beam using a post-lens deflector positioned below an objective lens of the miniature electron optical column comprises scanning.

61. The method of claim 55, wherein the adjusting one or more characteristics of the primary electron beam using a post-lens miniature optical element positioned below the objective lens of the miniature electron optical column, comprises:
applying one or more corrections to primary electron beam.

62. The method of claim 61, wherein the one or more corrections are configured to correct for at least one of:
astigmatism, field curvature, or offsets.

63. The method of claim 55, wherein the adjusting one or more characteristics of the primary electron beam using a post-lens miniature optical element positioned below the objective lens of the miniature electron optical column, comprises:
applying one or more dynamic focus corrections to the primary electron beam.

64. The method of claim 55, wherein the adjusting one or more characteristics of the primary electron beam using a post-lens miniature optical element positioned below the objective lens of the miniature electron optical column comprises scanning.

55. od of claim 55, wherein the adjusting one or more characteristics of the primary electron beam using a post-lens miniature optical element positioned below the objective lens of the miniature electron optical column, comprises:
varying an extraction field from the sample.

66. The method of claim 55, wherein the adjusting one or more characteristics of the primary electron beam using a post-lens miniature optical element positioned below the objective lens of the miniature electron optical column, comprises:
varying a termination field.

67. The method of claim 55, wherein the adjusting one or more characteristics of the primary electron beam using a post-lens miniature optical element positioned below the objective lens of the miniature electron optical column, comprises:
varying a focusing element.

68. The method of claim 55, wherein the adjusting one or more characteristics of the primary electron beam using one or more pre-lens deflectors positioned above an objective lens of the miniature electron optical column, comprises:
applying one or more corrections to primary electron beam.

69. The method of claim 68, wherein the one or more corrections are configured to correct for at least one of:
astigmatism or offsets.

70. The method of claim 55, wherein the adjusting one or more characteristics of the primary electron beam using one or more pre-lens deflectors positioned above an objective lens of the miniature electron optical column comprises scanning.
